(19) United States
(12) Patent Application Publication
(10) Pub. No.: US 2005/0149806 A1
(43) Pub. Date: Jul. 7, 2005

(54) Failure detection simulation system

(75) Inventor: Toshimasa Matsuura, Kanagawa (JP)

Correspondence Address: FOLEY AND LARDNER;SUITE 500, 3000 K STREET NW, WASHINGTON, DC, 20007, US

(73) Assignee: NEC Electronics Corporation

(21) Appl. No.: 10/999,946

(22) Filed: Dec. 1, 2004

(30) Foreign Application Priority Data
Dec. 2, 2003 (JP) 2003-403045

(51) Int. Cl. G06F 11/00; G01R 31/28

(52) U.S. Cl. 714/741

(57) ABSTRACT

A failure detection simulation system has a storage unit and a simulation unit. The storage unit stores a failure model parameter indicative of a characteristic of a failure status of a circuit element included in an analog circuit. The simulation unit executes a circuit simulation of the analog circuit in which the failure model parameter is applied to the circuit element by using expected input/output values as a test condition. The simulation unit detects a failure of the circuit element based on a result of the circuit simulation.

### BACKGROUND OF THE INVENTION

1. Field of the Invention

The present invention relates to a failure detection simulation system for detecting a failure in an analog circuit (integrated circuit) based on a circuit simulation. In particular, the present invention relates to a failure detection simulation system for obtaining a failure detection rate with regard to each circuit element of an analog circuit.

2. Description of the Related Art

Conventionally, a failure detection simulation for detecting a failure in a circuit has been generally carried out in the field of a digital circuit. As to an analog circuit, however, a failure detection simulation for detecting a failure with respect to each of circuit elements constituting the analog circuit has not been carried out. In the field of an analog circuit, only a test simulation for checking whether or not input/output values satisfy predetermined expected values (test condition) has been carried out.

In the failure detection simulation for a digital circuit, inputs and outputs of gates constituting the digital circuit are first defined. Then, the failure detection simulation is executed for each failure, and results of the failure detection are obtained. Failure models are also defined, and the circuit simulation is carried out for each failure by using a test pattern. Whether or not a failure is detected is judged on the basis of whether or not a simulation result is consistent with a pre-defined expected value.

As a conventional art with regard to the test simulation for an analog circuit, Japanese Laid Open Patent Application JP-A 2003-121511 (Patent document No. 1) discloses an IC test program generating device. In the IC test program generating device, a circuit simulation is executed with sequentially changing parameters that are the characteristic values of circuit elements in an IC circuit. Thus, the maximum and the minimum of standard test values can be obtained as a test condition. In this way, the test condition for which “dispersion” of the respective circuit elements is taken into consideration can be automatically generated.

As mentioned above, conventionally, a failure detection simulation for detecting a failure with respect to each of circuit elements constituting an analog circuit has not been carried out. The reason is as follows. Expected values as a test condition are not definitive enough to be able to distinguish normal and failure for each circuit element of the analog circuit. Thus, it is not possible to execute the failure detection simulation for detecting the failure.

Also, even in the conventional art disclosed in the above-mentioned patent document No. 1, only the test condition for which the dispersion of each circuit element is taken into consideration is generated by the test simulation of the analog circuit. It is not possible to generate a test condition for which the failure of each circuit element is taken into consideration.

### SUMMARY OF THE INVENTION

Therefore, an object of the present invention is to provide a failure detection simulation system which can determine a test condition to be applied to a failure detection test of an analog circuit.

Another object of the present invention is to provide a failure detection simulation system which can ensure failure detection with regard to each circuit element of an analog circuit.

In an aspect of the present invention, a failure detection simulation system has a storage unit and a simulation unit. The storage unit stores a failure model parameter indicative of a characteristic of a failure status of a circuit element included in an analog circuit. The simulation unit executes a circuit simulation of the analog circuit in which the failure model parameter is applied to the circuit element by using expected input/output values as a test condition. The simulation unit detects a failure of the circuit element based on a result of the circuit simulation.

The failure model parameter indicates a static characteristic of a failure status of the circuit element.

In the failure detection simulation system, the simulation unit determines that a failure of the circuit element is correctly detected when the result of the circuit simulation does not satisfy the expected input/output values. Then, the simulation unit calculates a failure detection rate with regard to the circuit element and outputs the failure detection rate as a failure detection simulation result.

In the failure detection simulation system, the storage unit stores a plurality of failure model parameters indicative of characteristics of respective of failure statuses of the circuit element. In this case, the simulation unit executes the circuit simulation by switching the failure model parameter applied to the circuit element from one of the plurality of failure model parameters to another.

The simulation unit determines for each of the plurality of failure model parameters that a failure of the circuit element is correctly detected when the result of the circuit simulation does not satisfy the expected input/output values. The simulation unit calculates failure detection rates for respective of the plurality of failure model parameters with regard to the circuit element, and outputs the failure detection rates as a failure detection simulation result.

In the failure detection simulation system, the simulation unit executes the circuit simulation with regard to the circuit element by changing the test condition from one of a plurality of test conditions to another one. In this case, the simulation unit can determine that a failure of the circuit element is correctly detected when the result of the circuit simulation with regard to any of the plurality of test conditions does not satisfy the expected input/output values. The simulation unit calculates a failure detection rate with regard to the circuit element and outputs the failure detection rate as a failure detection simulation result.

In the failure detection simulation system, the simulation unit can execute the circuit simulation for a plurality of circuit elements included in the analog circuit. In this case, the simulation unit can calculate a rate of a number of circuit elements in which the failure is correctly detected to a total number of the plurality of circuit elements. The simulation unit outputs the rate as a failure detection simulation result.

In another aspect of the present invention, a failure detection simulation system includes: a netlist indicative of a configuration of an analog circuit; a failure model parameter indicative of a characteristic of a failure status of a circuit element included in the analog circuit; a simulation circuit generating unit for generating a simulation circuit of the analog circuit in which the failure model parameter is applied to the circuit element; a test condition setting unit for setting expected input/output values of the circuit element as a test condition; and a simulating unit for executing a circuit simulation of the simulation circuit by using the test condition and for detecting a failure of the circuit element based on a result of the circuit simulation.

In the failure detection simulation system, the simulating unit determines that a failure of the circuit element is correctly detected when the result of the circuit simulation does not satisfy the expected input/output values.

The failure detection simulation system can further include a simulation result output unit for calculating a failure detection rate with regard to the circuit element based on the circuit simulation, and for outputting the failure detection rate as a failure detection simulation result.

The failure detection simulation system can further include: a plurality of failure model parameters indicative of characteristics of respective of failure statuses of the circuit element; and a simulation control unit for controlling the circuit simulation by switching the failure model parameter applied to the circuit element from one of the plurality of failure model parameters to another.

In the failure detection simulation system, the test condition setting unit changes the test condition from one of a plurality of test conditions to another. In this case, the simulating unit executes the circuit simulation with regard to the circuit element for each of the plurality of test conditions.

In still another aspect of the present invention, the failure detection simulation system can be realized by a computer program product which is executed by a computer. More specifically, the computer program product has computer readable codes configured to cause the computer to carry out the following steps: generating a simulation circuit of an analog circuit in which the failure model parameter is applied to the circuit element; setting expected input/output values of the circuit element as a test condition; executing a circuit simulation of the simulation circuit by using the test condition; detecting a failure of the circuit element based on a result of the circuit simulation; calculating a failure detection rate with regard to the circuit element based on the circuit simulation; and outputting the failure detection rate as a failure detection simulation result.

As described above, in the failure detection simulation system according to the present invention, the failure model parameters are prepared which define the failure models of respective of the circuit elements (transistor, resistance, capacitor and so on) in the analog circuit (integrated circuit). After a circuit element included in the netlist of the analog circuit is replaced by a corresponding one of the failure models, a circuit simulation is executed whose contents correspond to those of a delivery inspection of an integrated circuit. Thus, the failure detection rate for each of the circuit elements can be calculated.

According to the failure detection simulation system of the present invention, the following outstanding effects can be achieved.

Prior to a delivery inspection of an analog circuit (integrated circuit), the failure detection simulation is executed in which a failure model parameter is applied to each of circuit elements in the analog circuit. By calculating the failure detection rate for each circuit element, it becomes possible to inspect the test condition in order to increase the failure detection rate up to 100%. That is to say, based on the calculation result of the failure detection rate, it is possible to examine what kind of test condition should be applied to an actual test in order to ensure the failure detection.

By executing an actual delivery inspection based on the test condition thus obtained according to the failure detection simulation system, it becomes possible to improve a failure elimination rate and thus to promote the efficiency of the actual delivery inspection.

### BRIEF DESCRIPTION OF THE DRAWINGS

FIG. 1 is a block diagram showing a configuration of a failure detection simulation system according to an embodiment of the present invention;

FIG. 2 shows an example of a model parameter of an NPN transistor in the failure detection simulation system according to the embodiment;

FIG. 3 shows an example of a model parameter of a resistance in the failure detection simulation system according to the embodiment;

FIG. 4 shows an example of static characteristics (Ic-Vce characteristics) in a failure model and a normal model of the NPN transistor;

FIG. 5 shows an example of static characteristics (Vbe-Ic characteristics) in a failure model and a normal model of the NPN transistor;

FIG. 6 is a flow chart showing failure detecting operations of the failure detection simulation system according to the embodiment;

FIG. 7 is a flow chart showing the detail of a circuit simulation in the failure detecting operations according to the embodiment;

FIG. 8 shows an example of a circuit in which a normal model is used for a circuit element;

FIG. 9 shows an example of the circuit in which the circuit element in FIG. 8 is replaced by a failure model (open);

FIG. 10 shows an example of the circuit in which the circuit element in FIG. 8 is replaced by a failure model (short);

FIG. 11 shows an example of a simulation result outputted by the failure detection simulation system according to the embodiment;

FIG. 12 shows an example of a simulation result outputted by the failure detection simulation system in the case when all test items in a test condition are valid; and

FIG. 13 shows another example of a simulation result outputted by the failure detection simulation system according to the embodiment.

### DESCRIPTION OF THE PREFERRED EMBODIMENTS

Preferred embodiments of the present invention will be described below in detail with reference to the attached drawings.

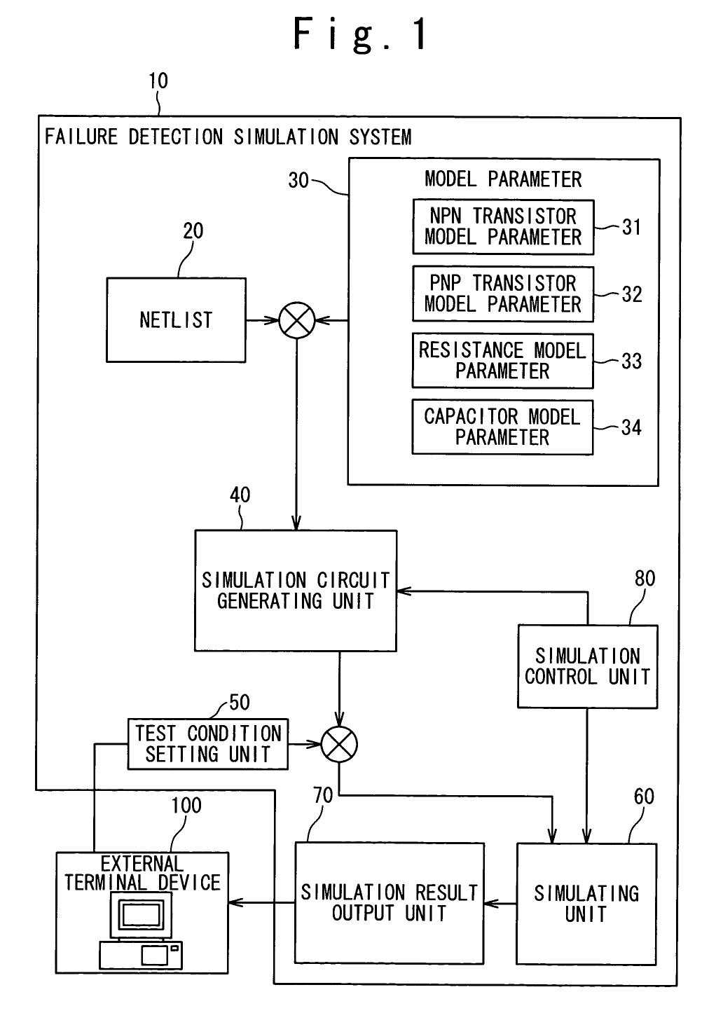

FIG. 1 shows a configuration of a failure detection simulation system according to an embodiment of the present invention.

A failure detection simulation system 10 in the present embodiment has a netlist 20, a model parameter 30, a simulation circuit generating unit 40, a test condition setting unit 50, a simulating unit 60, a simulation result output unit 70 and a simulation control unit 80. Also, the failure detection simulation system 10 is connected to an external terminal device 100.

This failure detection simulation system 10 may be configured by dedicated hardware. Also, the failure detection simulation system 10 can be attained by a program-controllable computer device (CPU) and software (failure detection simulation program) which is executable on the computer device. The failure detection simulation program is stored in a recording medium such as a magnetic disc, a semiconductor memory and the like. The failure detection simulation program is loaded from the recording medium into the computer device, and controls operations of the computer device to provide the following functions.

The netlist 20 is a list indicating a configuration (circuit specification) of an analog circuit (integrated circuit) which is the target for the failure detection. The net list 20 is stored in a storage unit of the failure detection simulation system 10. The storage unit is exemplified by a hard disk drive (HDD).

The model parameter 30 indicates characteristics of each of circuit elements contained in the analog circuit indicated by the netlist 20. Here, the characteristics of each circuit element is static characteristics. The circuit elements includes a transistor, a resistance, a capacitor and so on. For example, the model parameter 30 includes an NPN transistor model parameter 31, a PNP transistor model parameter 32, a resistance model parameter 33 and a capacitor model parameter 34. Also, the model parameter 30 for each circuit element has a “normal model parameter” and a “failure model parameter”. The normal model parameter defines a “normal model” of the circuit element and indicates a characteristic of a normal status of the circuit element. The failure model parameter defines a “failure model” of the circuit element and indicates a characteristic of a failure status of the circuit element. In the present embodiment, a plurality of failure model parameters (open, short) are prepared. The model parameter 30 is stored in the storage unit of the failure detection simulation system 10.

The simulation circuit generating unit 40 generates a “simulation circuit” which is used in a circuit simulation in the failure detection simulation system 10. More specifically, the simulation circuit generating unit 40 generates the simulation circuit by applying the parameters included in the model parameter 30 (failure model parameter) to respective of the circuit elements in the analog circuit indicated by the netlist 20. That is to say, a circuit element in the netlist 20 (the analog circuit) is replaced by a corresponding one of the failure models.

The test condition setting unit 50 sets a “test condition” which includes expected input/output values (voltage value and current values) with respect to each circuit element in the normal status. As the test condition for each of the circuit elements which is the target of the failure detection, a plurality of test items are set. The plurality of test items have different expected input/output values, each of which indicates a correspondence between a certain input value and an output value to be obtained in the normal status. Also, the test condition includes circuit information of a test tool used in an actual circuit inspection (for example, an IC inspector (tester)). In a circuit simulation, the test condition setting unit 50 can change the test item from one of the plurality of test items to another one.

The simulating unit 60 executes a “circuit simulation” of the simulation circuit generated by the simulation circuit generating unit 40. More specifically, the simulating unit 60 executes a circuit simulation for each of the circuit elements of the simulation circuit based on the test condition (the plurality of test items). Here, contents of the circuit simulation correspond to those of a delivery inspection of an integrated circuit. The circuit simulation is a general one. Refer to, for example, a circuit simulator disclosed in the above-mentioned patent document No. 1 (Japanese Laid Open Patent Application JP-A 2003-121511). The detailed explanations for the circuit simulation are omitted here.

The simulating unit 60 executes the circuit simulation for each circuit element by changing the test condition (test item). When a result of the circuit simulation satisfies the expected input/output values, it is determined that a failure of the circuit element can not be detected. When a result of the circuit simulation does not satisfy the expected input/output values, it is determined that a failure of the circuit element is correctly detected. Thus, on the basis of a result of the circuit simulation, the simulating unit 60 can detect a failure of the circuit element.

The simulating unit 60 can be constituted by dedicated hardware. Also, the simulating unit 60 can be attained by software (failure detection simulation program) that is executed on the computer device and can simulate a test using the actual test tools such as a tester.

After the circuit simulation is executed for all the test conditions, the simulation result output unit 70 calculates a “failure detection rate” with regard to the circuit element, based on the result of the circuit simulation executed by the simulating unit 60. Then, the simulation result output unit 70 outputs information including the failure detection rate as a failure detection simulation result. The information may include the failure detection rates calculated for respective of the circuit elements. The failure detection simulation result is sent to the external terminal device 100.

The simulation control unit 80 judges whether or not the circuit simulation of the target circuit element is completed for all of the failure model parameters. Also, the simulation control unit 80 controls the circuit simulation executed by the simulating unit 60. More specifically, the simulation control unit 80 switches the failure model parameter applied to the target circuit element from one of the plurality of failure model parameters to another one, and controls the simulating unit 60 to execute the circuit simulation based on the other failure model parameter.

Next, the operations of the above-mentioned failure detection simulation system 10 according to the present embodiment will be described below.

First, prior to a failure detection simulation, a model parameter including the “normal model parameter” and the “failure model parameters” is prepared for each circuit element, and is stored as the model parameter 30 in a storage unit.

In the present embodiment, as shown in FIG. 1, the model parameter 30 includes a model parameter 31 for an NPN transistor, a model parameter 32 for a PNP transistor, a model parameter 33 for a resistance and a model parameter 34 for a capacitor.

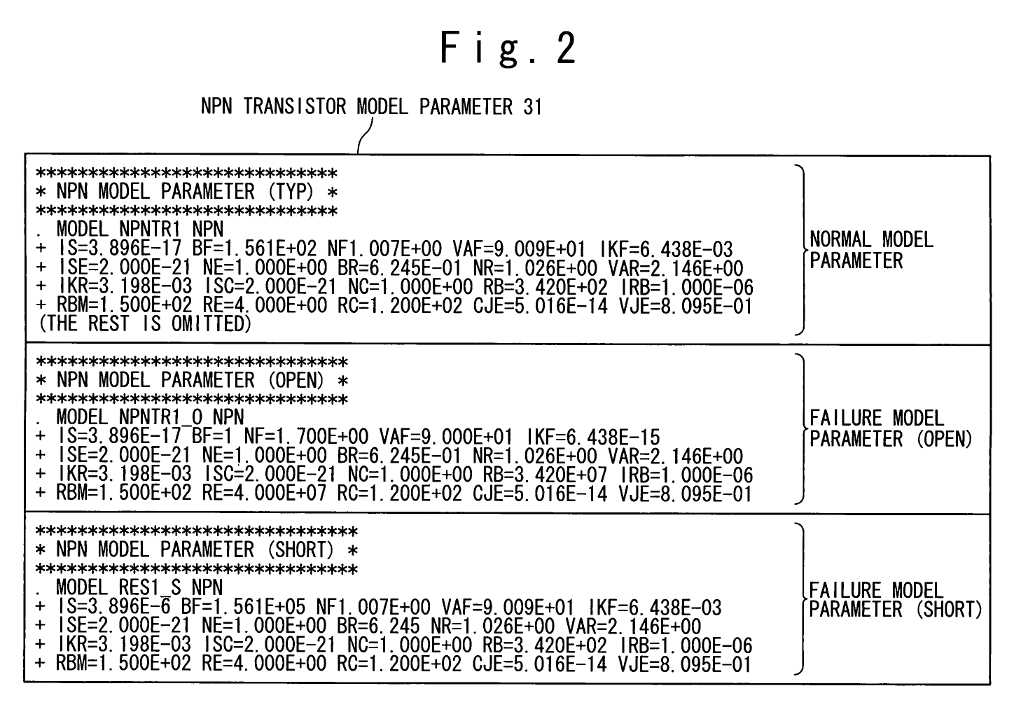

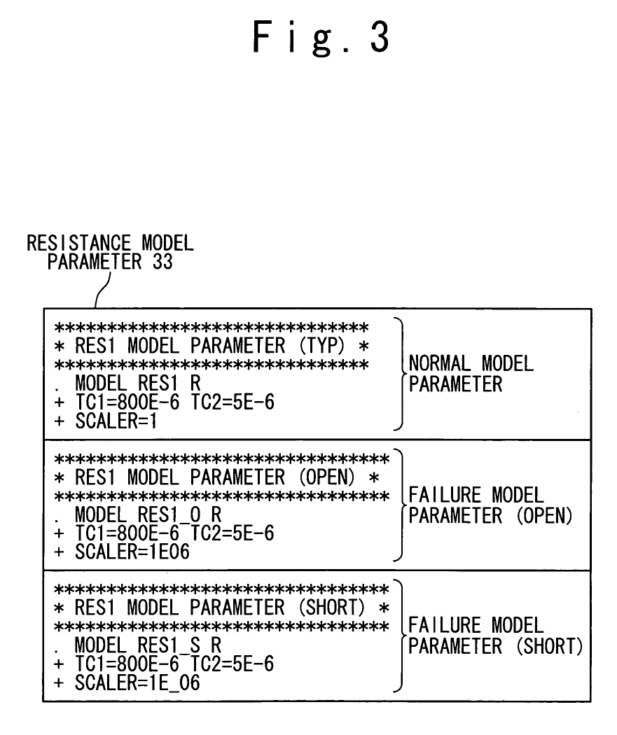

FIGS. 2, 3 show examples of the NPN transistor model parameter 31 and the resistance model parameter 33, respectively.

FIG. 2 shows contents of the NPN transistor model parameter 31. The NPN transistor model parameter 31 includes a normal model parameter, a failure model parameter indicating the open failure of the NPN transistor, and a failure model parameter indicating the short failure of the NPN transistor. Also, FIG. 3 shows contents of the resistance model parameter 33. The resistance model parameter 33 includes a normal model parameter, a failure model parameter indicating the open failure of the resistance, and a failure model parameter indicating the short failure of the resistance.

At least one failure model parameter is set with respect to each circuit element. Also, values which depart largely from the range of the characteristic dispersion occurred in the manufacturing process of the circuit element (values indicating the open state or the short state) are set as the failure model parameter.

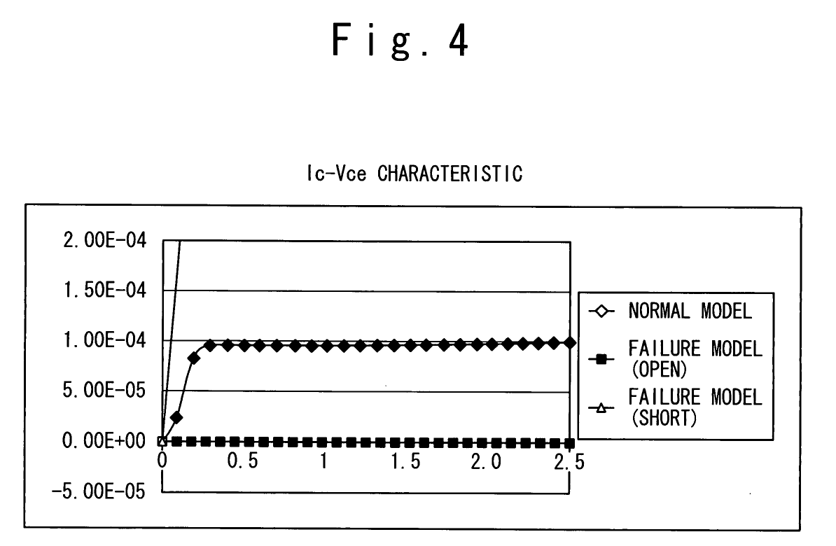

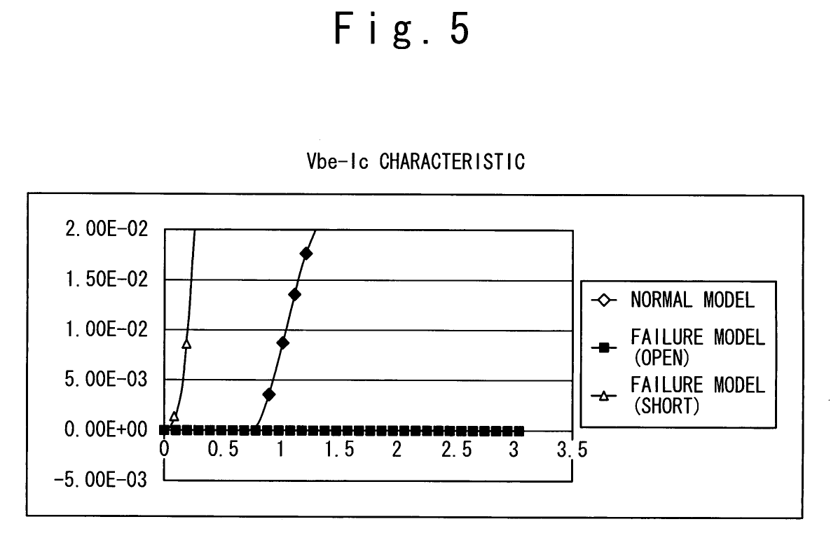

Also, FIG. 4 shows Ic-Vce characteristics which are the static characteristics for the above-mentioned failure models (open and short) and the normal model of the NPN transistor. Also, FIG. 5 shows Vbe-Ic characteristics which are the static characteristics for the above-mentioned failure models (open and short) and the normal model of the NPN transistor. The static characteristics according to the failure model parameters and the normal model parameter shown in FIG. 2 are shown.

In the description above, the examples of the model parameters with regard to the transistor and the resistance are shown. As in the case above, the model parameter 34 of the capacitor also includes a normal model parameter and a failure model parameter.

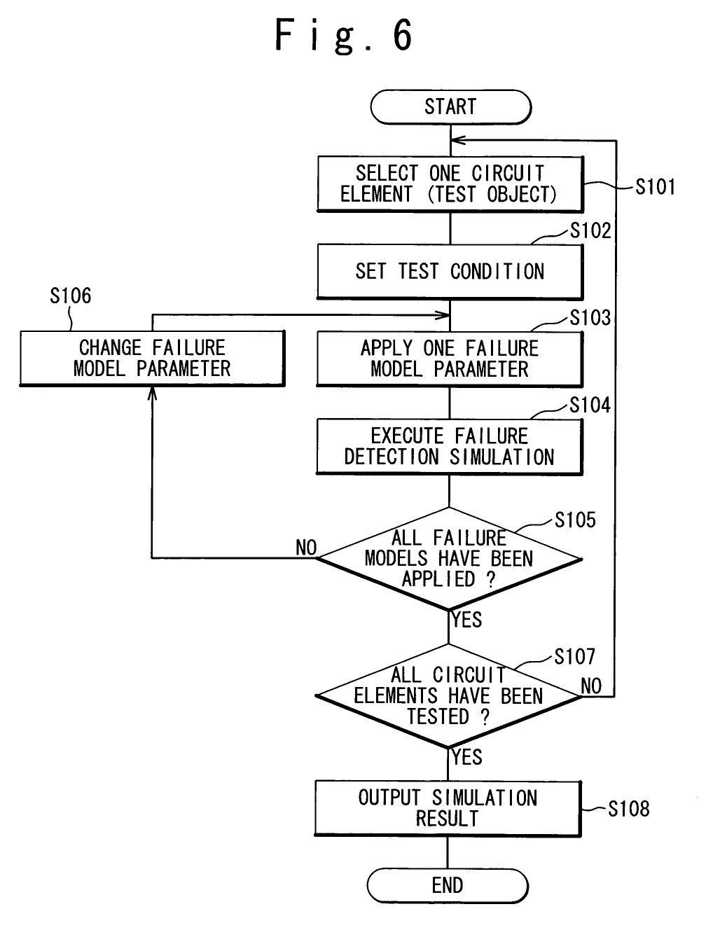

The failure detecting operations of the failure detection simulation system 10 according to the present embodiment will be explained with reference to a flow chart shown in FIG. 6.

A circuit element as an inspection target is selected from the analog circuit indicated by the netlist 20 (Step S101). Here, the target circuit element is selected from the circuit elements such as the NPN transistor, the resistance and the like contained in the netlist 20.

Next, a test condition for the selected target circuit element is set (Step S102). Here, the test condition including a plurality of test items (expected input/output values) prepared for each circuit element is set. As the plurality of test items, a plurality of combinations of an input value and an output value are prepared. For example, the number of the test items is 100. A case when 100 test items are set will be explained hereafter as an example.

Then, the simulation circuit generating unit 40 applies one failure model parameter corresponding to the target circuit element in the model parameter 30 to the selected target circuit element. Thus, a simulation circuit including a failure model of the circuit element is generated (Step S103).

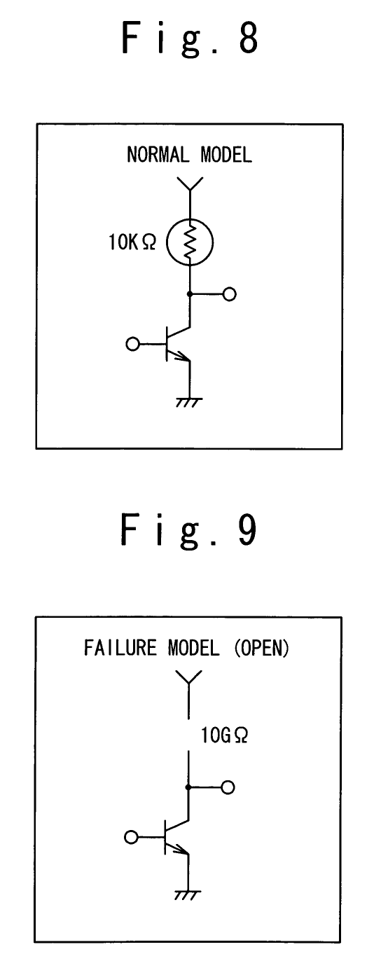

For example, the failure model parameter indicating the open status is applied to a resistance included in an analog circuit of the normal model shown in FIG. 8. As a result, a simulation circuit of the failure model shown in FIG. 9 is generated.

Next, a circuit simulation of the above-mentioned simulation circuit of the failure model is executed by using the test condition as set above (Step S104). Here, contents of the circuit simulation correspond to those of a delivery inspection of an integrated circuit.

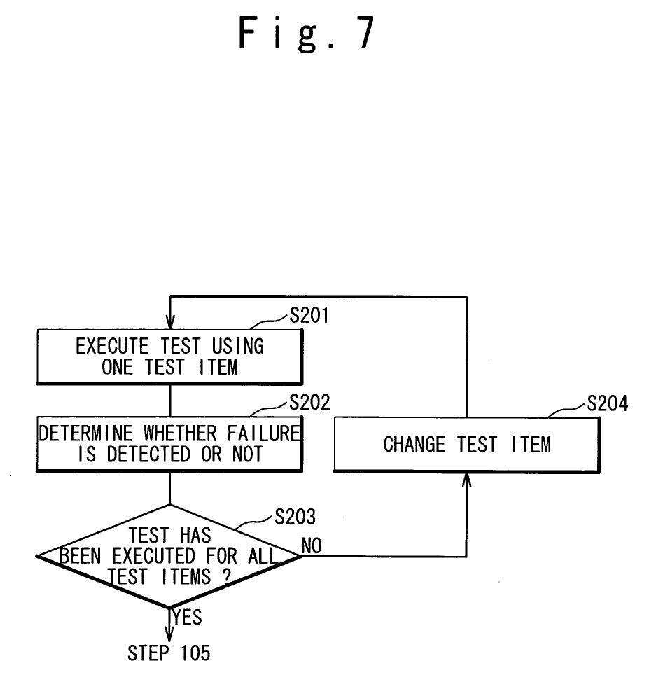

The circuit simulation on the basis of the test condition is executed in accordance with a flow chart shown in FIG. 7.

First, a test (circuit simulation) is executed by using one test item included in the test condition (Step S201).

As a result of the test, whether or not a failure is detected with regard to the one test item is determined. That is to say, whether the result is consist with the expected values corresponding to the test item or not is determined (Step S202). In the case when the result of the circuit simulation satisfies the expected values (the result is within the allowable limits), it is determined that the failure of the target circuit element is not correctly detected. On the other hand, in the case when the result of the circuit simulation does not satisfy the expected values (the result is beyond the allowable limits), it is determined that the failure of the target circuit element is correctly detected. Whether the failure is detected or not is recorded.

After that, whether or not the test is executed for all the test items set as the test condition is judged (Step S203). If any test remains unexecuted (Step S203; No), the test item is changed to the next test item (Step S204), and the next test is carried out (Step S201).

For example, if there are 100 test items, the test is repeatedly executed for a hundred times for respective of the 100 test items. When the test is executed for all the test items (Step S203; Yes), the test for the applied one failure model is completed. The test results for all the test items as to whether the failure is detected or not are recorded with regard to the failure model.

After the circuit simulation (Step S104) of the simulation circuit which is generated in the Step S103 and includes the applied one failure model is completed, whether or not all the failure model parameters (failure models) corresponding to the target circuit element have been applied is judged (Step S105). If another failure model parameter remains (Step S105; No), the simulation control unit 80 switches the failure model parameter applied to the target circuit element to the other failure model parameter (Step S106). Thus, another simulation circuit including another failure model of the target circuit element is generated (Step S103), and the failure detection simulation is executed for the other simulation circuit (Step S104).

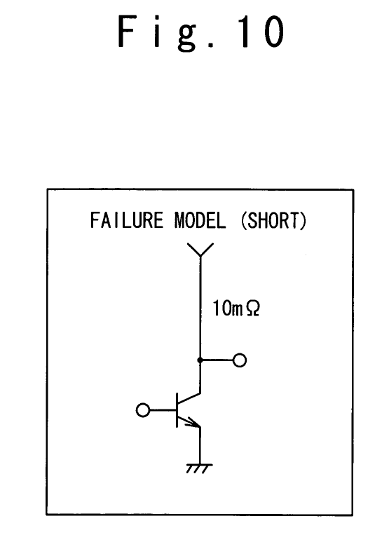

For example, after a simulation of the simulation circuit of the failure model (open model) shown in FIG. 9 is completed, the other failure model parameter indicating the short status is applied to the resistance. As a result, the other simulation circuit of the failure model (short model) shown in FIG. 10 is generated. Then, another circuit simulation is executed for detecting the short failure.

The circuit simulation for the target circuit element is repeatedly executed until all of the corresponding failure model parameters are applied.

If the failure detection simulations with regard to respective of the failure model parameters for the target circuit element is completed (Step S105; Yes), whether the circuit simulations for all of the circuit elements in the integrated circuit indicated by the netlist 20 are completed or not is judged (Step S107).

If an unexamined circuit element still remains (Step S107; No), the unexamined circuit element is selected as a new target circuit element (Step S101), and a new test condition is set for the new target circuit element (Step S102). Then, the above-mentioned processes from the Step S103 to the Step S106 are repeated.

If the circuit simulations for all the circuit elements in the integrated circuit indicated by the netlist 20 are completed (Step S107; Yes), the test results for each circuit element are outputted as a “failure detection simulation result” (Step S108).

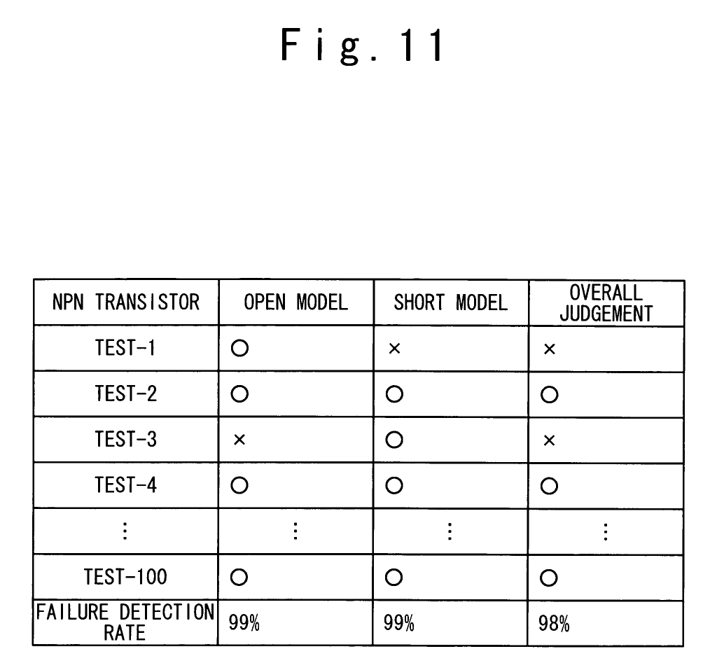

FIG. 11 shows the failure detection simulation results with regard to the 100 test items (Test-1 to Test-100). In FIG. 11, the failure detection simulation results are shown for both the failure models (the open model and the short model) of the NPN transistor as the target circuit element. Also, in FIG. 11, a circle denotes that a failure is correctly detected, and a cross denotes that a failure is not detected.

FIG. 11 shows that the failure is not detected in the test item Test-3 for the open model and that the failure is not detected in the test item Test-1 for the short model. An overall judgment is also shown for every test item in FIG. 11, which indicates whether or not the failure is detected for all the failure models.

Also, “failure detection rates” are shown for respective of the open model, short model and the combination of them (overall judgment). Here, the failure detection rate (%) can be given by (the number of test items associated with failure detection indicated by the circle/the total number of the test items)*100.

In the example shown in FIG. 11, the failure is not detected only in the test item Test-3 for the open model. Therefore, the failure detection rate for the open model is calculated to be 99%. Similarly, the failure is not detected only in the test item Test-1 for the short model. Therefore, the failure detection rate for the short model is calculated to be 99%. If the failure is not detected in 10 test items out of 100 test items, for example, the failure detection rate is calculated to be 90%.

Thus, the failure detection rate of the target circuit element (NPN transistor) in the overall judgment is 98% as shown in FIG. 11. If the failure detection rate in the overall judgment is 100%, it is verified that all the test items are valid.

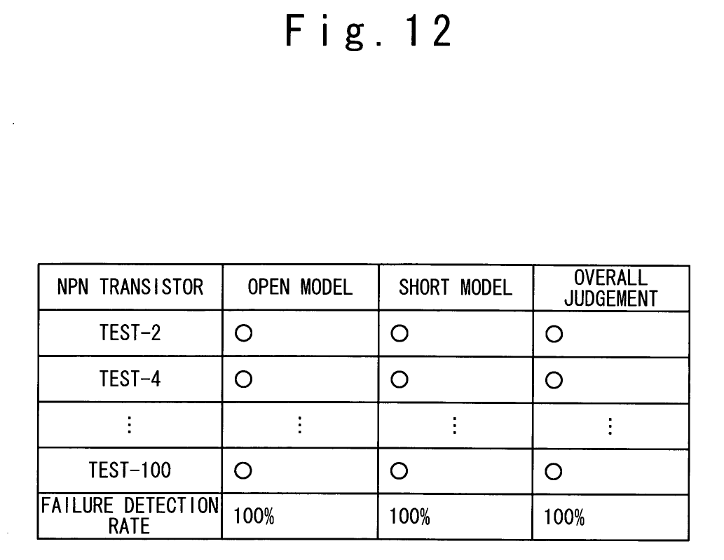

In the test result shown in FIG. 11, the test items indicated by the crosses in the overall judgment are not determined to be valid, since the failure can not be detected for at least any of the failure models by using such test items. When such invalid test items (Test-1 and Test-3 in the case of FIG. 11) are eliminated from the plurality of test items included in the test condition, a modified test condition including 98 valid test items can be obtained. If the failure detection simulation is executed by using the modified test condition as a new test condition, a failure detection simulation result as shown in FIG. 12 would be obtained. In the failure detection simulation result shown in FIG. 12, the failure detection rates for all of the failure models are calculated to be 100%.

According to the failure detection simulation system 10, as described above, it is possible to inspect the test condition based on the failure detection simulation result. The failure detection simulation result is useful for obtaining only valid test items as the test condition. By executing an actual delivery inspection based on the test condition thus obtained, it is possible to increase the failure detection rate up to 100% in the actual delivery inspection. Thus, the test quality can be improved and the efficiency of the actual delivery inspection can be promoted.

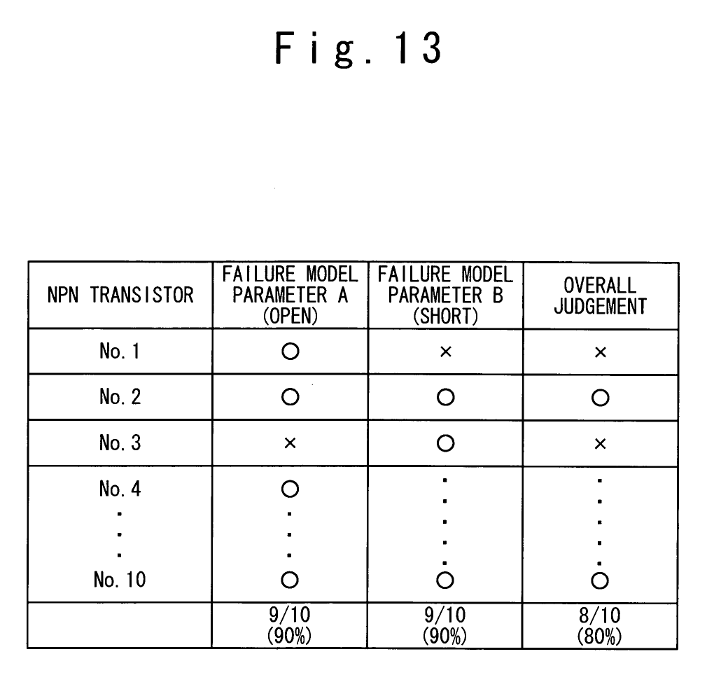

FIG. 13 shows another example of the failure detection simulation result.

Shown in the example in FIG. 13 is not the result for each test item. Instead, whether or not the failure is detected is shown with regard to each of 10 NPN transistors (No. 1-No. 10). Whether or not the failure is detected is shown for a failure model parameter A (for example, the open model) and a failure model parameter B (for example, the short model) independently.

According to this failure detection simulation result, the failure detection with regard to each NPN transistor (circuit element) is judged based on all the test items which are set as the test condition. In the case when the result of the circuit simulation with regard to any of the all test items does not satisfy the expected values (the result is beyond the allowable limits), it is determined that the failure of the target circuit element is correctly detected. In the case when the results of all the circuit simulations with regard to all the test items satisfy the expected values (the result is within the allowable limits), it is determined that the failure of the target circuit element is not detected.

In FIG. 13, a circle denotes that a failure is correctly detected, and a cross denotes that a failure is not detected. As for the NPN transistor No. 1, the failure is detected for the failure model parameter A, but the failure is not detected for the failure model parameter B.

Also, an overall judgment is shown for every transistor (circuit element), which indicates whether or not the failure is detected for all the failure models. As for the NPN transistor No. 1, for example, the overall judgment is that the failure is not detected correctly, because the failure is detected for the failure model parameter A but the failure is not detected for the failure model parameter B In this simulation result, the failure detection rate for the failure model parameter A is 90%, since the failure is not detected in the NPN transistor No. 3. Also, the failure detection rate for the failure model parameter B is 90%, since the failure is not detected in the NPN transistor No. 1. Therefore, the failure detection rate with regard to all the 10 NPN transistors (overall judgment) is 80%.

Also, a failure detection rate with regard to the entire analog circuit can be calculated and outputted as the failure detection simulation result in addition to the result shown in FIG. 13. The failure detection rate of the entire analog circuit is given by (the number of circuit elements in which the failure is correctly detected in the overall judgment/the total number of all the circuit elements)*100.

For example, let us consider an analog circuit (integrated circuit) including 10 transistors and 20 resistances. According to the overall judgment, the failure is correctly detected in 8 transistors out of the 10 transistors and in 13 resistances out of the 20 resistances. In this case, the failure detection rate for the entire integrated circuit is calculated to be 70% (21/30).

In the failure detection simulation mentioned above, if the set test condition (the plurality of test items) is appropriate, the failure detection rate should be 100%. If the failure detection rate does not reach 100%, the set test condition is considered to include some inappropriate values. Therefore, by executing the failure detection simulation prior to an actual delivery inspection, it is possible to inspect the test condition in order to increase the failure detection rate. That is to say, based on the failure detection simulation result, it is possible to examine what kind of test condition should be applied to the actual delivery inspection in order to ensure the failure detection. The failure detection simulation result is useful for obtaining only valid test items as the test condition. By executing the actual delivery inspection based on the test condition thus obtained, it is possible to increase the failure detection rate up to 100%. Thus, the test quality and failure elimination rate can be improved and the efficiency of the actual delivery inspection can be promoted.

It should be noted that the failure detection simulation system 10 can be realized by a computer program product which is executed by a computer. The computer program product has computer readable codes configured to cause the computer to carry out the following steps: generating a simulation circuit of an analog circuit in which the failure model parameter is applied to the circuit element; setting expected input/output values of the circuit element as a test condition; executing a circuit simulation of the simulation circuit by using the test condition; detecting a failure of the circuit element based on a result of the circuit simulation; calculating a failure detection rate with regard to the circuit element based on the circuit simulation; and outputting the failure detection rate as a failure detection simulation result.

It will be obvious to one skilled in the art that the present invention may be practiced in other embodiments that depart from the above-described specific details. The scope of the present invention, therefore, should be determined by the following claims.

1. A failure detection simulation system comprising:
a storage unit configured for storing a failure model parameter indicative of a characteristic of a failure status of a circuit element included in an analog circuit; and
a simulation unit configured for executing a circuit simulation of said analog circuit in which said failure model parameter is applied to said circuit element by using expected input/output values as a test condition, and for detecting a failure of said circuit element based on a result of said circuit simulation.

2. The failure detection simulation system according to claim 1,
wherein said simulation unit determines that a failure of said circuit element is correctly detected when said result of said circuit simulation does not satisfy said expected input/output values.

3. The failure detection simulation system according to claim 2,
wherein said simulation unit calculates a failure detection rate with regard to said circuit element and outputs said failure detection rate as a failure detection simulation result.

4. The failure detection simulation system according to claim 1,
wherein said storage unit stores a plurality of failure model parameters indicative of characteristics of respective of failure statuses of said circuit element, and
said simulation unit executes said circuit simulation by switching said failure model parameter applied to said circuit element from one of said plurality of failure model parameters to another.

5. The failure detection simulation system according to claim 4,
wherein said simulation unit determines for each of said plurality of failure model parameters that a failure of said circuit element is correctly detected when said result of said circuit simulation does not satisfy said expected input/output values.

6. The failure detection simulation system according to claim 5,
wherein said simulation unit calculates failure detection rates for respective of said plurality of failure model parameters with regard to said circuit element, and outputs said failure detection rates as a failure detection simulation result.

7. The failure detection simulation system according to claim 1,
wherein said simulation unit executes said circuit simulation with regard to said circuit element by changing said test condition from one of a plurality of test conditions to another.

8. The failure detection simulation system according to claim 7,
wherein said simulation unit determines that a failure of said circuit element is correctly detected when said result of said circuit simulation with regard to any of said plurality of test conditions does not satisfy said expected input/output values.

9. The failure detection simulation system according to claim 8,
wherein said simulation unit calculates a failure detection rate with regard to said circuit element and outputs said failure detection rate as a failure detection simulation result.

10. The failure detection simulation system according to claim 8,
wherein said simulation unit executes said circuit simulation for a plurality of circuit elements included in said analog circuit, calculates a rate of a number of circuit elements in which said failure is correctly detected to a total number of said plurality of circuit elements, and outputs said rate as a failure detection simulation result.

11. A failure detection simulation system comprising:
a netlist indicative of a configuration of an analog circuit;
a failure model parameter indicative of a characteristic of a failure status of a circuit element included in said analog circuit;
a simulation circuit generating unit for generating a simulation circuit of said analog circuit in which said failure model parameter is applied to said circuit element;
a test condition setting unit for setting expected input/output values of said circuit element as a test condition; and
a simulating unit for executing a circuit simulation of said simulation circuit by using said test condition and for detecting a failure of said circuit element based on a result of said circuit simulation.

12. The failure detection simulation system according to claim 11,
wherein said simulating unit determines that a failure of said circuit element is correctly detected when said result of said circuit simulation does not satisfy said expected input/output values.

13. The failure detection simulation system according to claim 12, further comprising a simulation result output unit for calculating a failure detection rate with regard to said circuit element based on said circuit simulation, and for outputting said failure detection rate as a failure detection simulation result.

14. The failure detection simulation system according to claim 11, further comprising:
a plurality of failure model parameters indicative of characteristics of respective of failure statuses of said circuit element; and
a simulation control unit for controlling said circuit simulation by switching said failure model parameter applied to said circuit element from one of said plurality of failure model parameters to another.

15. The failure detection simulation system according to claim 11,
wherein said test condition setting unit changes said test condition from one of a plurality of test conditions to another, and
said simulating unit executes said circuit simulation with regard to said circuit element for each of said plurality of test conditions.

16. A computer program product for detecting a failure of an analog circuit, which is executed by a computer having a storage unit storing a failure model parameter indicative of a characteristic of a failure status of a circuit element included in said analog circuit, comprising:
a computer readable code configured to cause said computer to generate a simulation circuit of said analog circuit in which said failure model parameter is applied to said circuit element;
a computer readable code configured to cause said computer to set expected input/output values of said circuit element as a test condition; and
a computer readable code configured to cause said computer to execute a circuit simulation of said simulation circuit by using said test condition, and to detect a failure of said circuit element based on a result of said circuit simulation.

17. The computer program product according to claim 16, further comprising a computer readable code configured to cause said computer to calculate a failure detection rate with regard to said circuit element based on said circuit simulation, and to output said failure detection rate as a failure detection simulation result.

18. The computer program product according to claim 16, in which said storage unit stores a plurality of failure model parameters indicative of characteristics of respective of failure statuses of said circuit element, further comprising a computer readable code configured to cause said computer to control said circuit simulation by switching said failure model parameter applied to said circuit element from one of said plurality of failure model parameters to another.

19. The computer program product according to claim 16, further comprising a computer readable code configured to cause said computer to calculate a rate of a number of circuit elements in which said failure is detected to a total number of circuit elements based on said circuit simulation, and output said rate as said failure detection simulation result.

20. The failure detection simulation system according to claim 1,
wherein said failure model parameter indicates a static characteristic of a failure status of said circuit element.
